(19) United States
(12) Patent Application Publication
(10) Pub. No.: US 2017/0134030 A1
(43) Pub. Date: May 11, 2017

(54) ALL-DIGITAL PHASE LOCK LOOP SPUR REDUCTION USING A CRYSTAL OSCILLATOR FRACTIONAL DIVIDER

(71) Applicant: QUALCOMM Incorporated, San Diego, CA (US)

(72) Inventors: Mahbod MOFIDI, San Diego, CA (US); Emanuele LOPELLI, Laguna Niguel, CA (US); Magnus Olov WIKLUND, San Jose, CA (US); Charles WANG, Irvine, CA (US)

(21) Appl. No.: 15/163,480

(22) Filed: May 24, 2016

Related U.S. Application Data
(60) Provisional application No. 62/251,915, filed on Nov. 6, 2015.

(51) Int. Cl. H03L 7/10; H03L 7/099; H03L 7/197; H03L 7/113; H03L 7/091; H03B 5/32; H03B 1/04

(52) U.S. Cl. CPC H03L 7/104; H03B 5/32; H03L 7/0991; H03B 1/04; H03L 7/113; H03L 7/091; H03L 7/1974; H03L 2207/50

(57) ABSTRACT

Disclosed are methods and apparatuses for reducing fractional spurs in an All-Digital Phase Lock Loop (ADPLL). An exemplary apparatus includes a crystal oscillator configured to generate a first frequency reference signal, a non-integer divider coupled to the crystal oscillator and configured to divide the first frequency reference signal by a non-integer variable to generate a second frequency reference signal, and a multiplexor coupled to the non-integer divider and the crystal oscillator and configured to output the first frequency reference signal or the second frequency reference signal to the ADPLL, wherein the multiplexor is configured to output the second frequency reference signal based on the ADPLL being tuned to a low fractionality channel.

### CROSS-REFERENCE TO RELATED APPLICATIONS

The present Application for Patent claims the benefit of U.S. Provisional Application No. 62/251,915, entitled “ALL-DIGITAL PHASE LOCK LOOP SPUR REDUCTION USING A CRYSTAL OSCILLATOR FRACTIONAL DIVIDER,” filed Nov. 6, 2015, assigned to the assignee hereof, and expressly incorporated herein by reference in its entirety.

### INTRODUCTION

Aspects of the disclosure relate to spur reduction in an All-digital Phase Lock Loop (ADPLL) using a crystal oscillator (XO) fractional divider.

Lower power consumption is an important criteria for many modern battery-powered electronic devices, for example, smaller Internet of Things (IoT) devices that operate on one or more “button” batteries and communicate wirelessly using protocols such as Bluetooth® Low Energy (BLE), BLE Long Range, Bluetooth® Basic Rate (BR), Bluetooth® Enhanced Data Rate (EDR), IEEE 802.15.4 Zigbee, Wireless Local Area Network (WLAN) (802.11a/b/g/n/ah/ac), and the like.

Employing All-digital PLLs (ADPLLs) within these devices can significantly lower their power consumption as compared to analog PLLs (APLLs). However, the benefit of using an ADPLL comes at the cost of higher spurs and phase noise that could lead to degradation in the performance of both the receiver and the transmitter devices. As a result, the receiver and transmitter devices may have difficulty meeting some of the specifications defined in the protocol standards mentioned above.

### SUMMARY

The following presents a simplified summary relating to one or more aspects and/or embodiments associated with the mechanisms disclosed herein for reducing spurs in an All-Digital Phase Lock Loop (ADPLL) using a crystal oscillator (XO) fractional divider. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

An apparatus for reducing fractional spurs in an ADPLL includes a crystal oscillator configured to generate a first frequency reference signal, a non-integer divider coupled to the crystal oscillator and configured to divide the first frequency reference signal by a non-integer variable to generate a second frequency reference signal, and a multiplexor coupled to the non-integer divider and the crystal oscillator and configured to output the first frequency reference signal or the second frequency reference signal to the ADPLL, wherein the multiplexor is configured to output the second frequency reference signal based on the ADPLL being tuned to a low fractionality channel.

A method for reducing fractional spurs in an ADPLL includes generating, by a crystal oscillator, a first frequency reference signal, generating, by a non-integer divider coupled to the crystal oscillator, a second frequency reference signal by dividing the first frequency reference signal by a non-integer variable, and outputting to the ADPLL, by a multiplexor coupled to the non-integer divider and the crystal oscillator, the first frequency reference signal or the second frequency reference signal, wherein the multiplexor is configured to output the second frequency reference signal based on the ADPLL being tuned to a low fractionality channel.

An apparatus for reducing fractional spurs in an ADPLL includes a frequency reference signal generating means for generating a first frequency reference signal, a divider means, coupled to the frequency reference signal generating means, for dividing the first frequency reference signal by a non-integer variable to generate a second frequency reference signal, and a multiplexing means, coupled to the divider means and the frequency reference signal generating means, for outputting the first frequency reference signal or the second frequency reference signal to the ADPLL, wherein the multiplexing means outputs the second frequency reference signal based on the ADPLL being tuned to a low fractionality channel.

Other objects and advantages associated with the mechanisms disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof

FIG. 1 illustrates an example wireless communication system including an Access Point (AP) in communication with an Access Terminal (AT).

FIG. 2 is a simplified block diagram of an exemplary All-Digital Phase Lock Loop (ADPLL).

FIG. 3 is a simplified block diagram of an exemplary ADPLL.

FIG. 4 is a simplified block diagram of an exemplary system in which the ADPLL of FIG. 2 receives input from a non-integer divider according to at least one aspect of the disclosure.

FIG. 5 is a simplified block diagram of an exemplary system in which the ADPLL of FIG. 3 receives input from a non-integer divider according to at least one aspect of the disclosure.

FIG. 6 illustrates a graph of simulation results of a system employing the mechanisms described herein for reducing spurs in an ADPLL using a non-integer divider.

FIG. 7 is a flow diagram illustrating an example method for reducing spurs in an ADPLL using a non-integer divider in accordance with the techniques described herein.

FIG. 8 is a simplified block diagram of several sample aspects of an apparatus according to at least one aspect described herein.

### DETAILED DESCRIPTION

The present disclosure relates generally to reducing spurs in an All-Digital Phase Lock Loop (ADPLL) using a crystal oscillator (XO) fractional divider. An exemplary apparatus includes an XO configured to generate a first frequency reference signal, a non-integer divider coupled to the XO and configured to divide the first frequency reference signal by a non-integer variable to generate a second frequency reference signal, and a multiplexor coupled to the non-integer divider, and the XO and configured to output the first frequency reference signal or the second frequency reference signal to the ADPLL, wherein the multiplexor is configured to output the second frequency reference signal based on the ADPLL being tuned to a low fractionality channel.

These and other aspects of the disclosure are provided in the following description and related drawings directed to various examples provided for illustration purposes. Alternate aspects may be devised without departing from the scope of the disclosure. Additionally, well-known aspects of the disclosure may not be described in detail or may be omitted so as not to obscure more relevant details.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., Application Specific Integrated Circuits (ASICs)), by program instructions being executed by one or more processors, or by a combination of both. In addition, for each of the aspects described herein, the corresponding form of any such aspect may be implemented as, for example, “logic configured to” perform the described action.

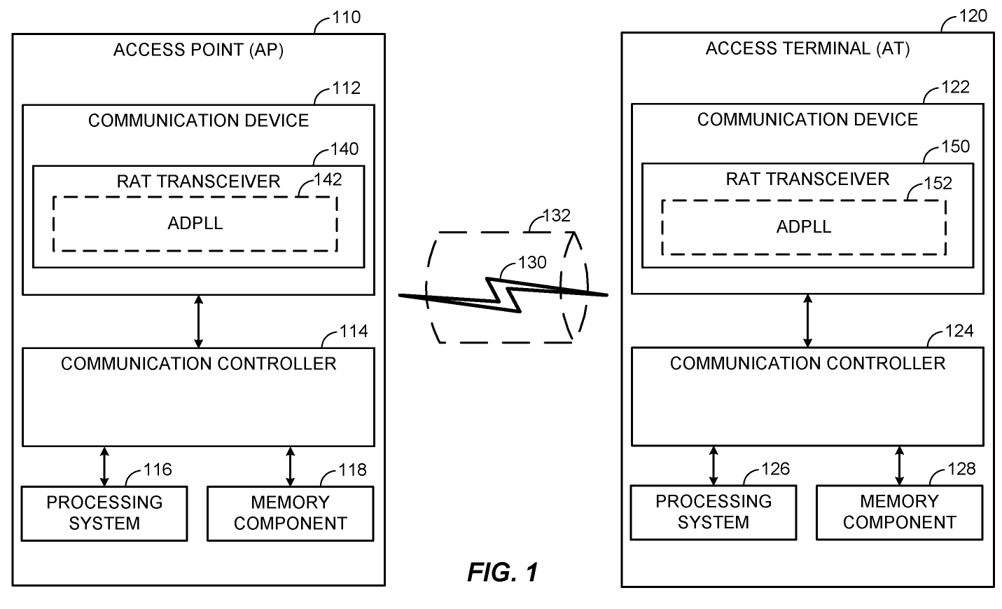

FIG. 1 illustrates an example wireless communication system including an Access Point (AP) 110 in communication with an Access Terminal (AT) 120. Unless otherwise noted, the terms “access terminal” and “access point” are not intended to be specific or limited to any particular Radio Access Technology (RAT). In general, access terminals may be any wireless communication device allowing a user to communicate over a communications network (e.g., a mobile phone, router, personal computer, server, entertainment device, Internet of Things (IoT)/Internet of Everything (IoE) capable device, in-vehicle communication device, etc.), and may be alternatively referred to in different RAT environments as a User Device (UD), a Mobile Station (MS), a Subscriber Station (STA), a User Equipment (UE), etc.

Similarly, an access point may operate according to one or several RATs in communicating with access terminals depending on the network in which the access point is deployed, and may be alternatively referred to as a Base Station (BS), a Network Node, a NodeB, an evolved NodeB (eNB), etc. Such an access point may correspond to a small cell access point, for example. “Small cells” generally refer to a class of low-powered access points that may include or be otherwise referred to as femto cells, pico cells, micro cells, Wi-Fi APs, other small coverage area APs, etc. Small cells may be deployed to supplement macro cell coverage, which may cover a few blocks within a neighborhood or several square miles in a rural environment, thereby leading to improved signaling, incremental capacity growth, richer user experience, and so on.

In the example of FIG. 1, the access point 110 and the access terminal 120 each generally include a wireless communication device (represented by communication devices 112 and 122) for communicating with other network nodes via at least one designated RAT. The communication devices 112 and 122 may be variously configured for transmitting and encoding signals (e.g., messages, indications, information, and so on), and, conversely, for receiving and decoding signals (e.g., messages, indications, information, pilots, and so on) in accordance with the designated RAT. The communication device 112 of the access point 110 includes an RAT transceiver 140 configured to operate in accordance with a given RAT (e.g., Bluetooth®, Bluetooth® Low Energy, Wi-Fi, etc.). Similarly, the communication device 122 of the access terminal 120 includes an RAT transceiver 150 configured to operate in accordance with the RAT. As used herein, a “transceiver” may include a transmitter circuit, a receiver circuit, or a combination thereof, but need not provide both transmit and receive functionalities in all designs. For example, a low functionality receiver circuit may be employed in some designs to reduce costs when providing full communication is not necessary (e.g., a Wi-Fi chip or similar circuitry simply providing low-level sniffing). The RAT transceivers 140 and 150 may include an All-Digital Phase Lock Loop (ADPLL) 142 and an ADPLL 152, respectively, as will be described further herein.

The access point 110 and the access terminal 120 may also each generally include a communication controller (represented by communication controllers 114 and 124) for controlling operation of their respective communication devices 112 and 122 (e.g., directing, modifying, enabling, disabling, etc.). The communication controllers 114 and 124 may operate at the direction of, or otherwise in conjunction with, respective host system functionality (illustrated as processing systems 116 and 126 and memory components 118 and 128). In some designs, the communication controllers 114 and 124 may be partly or wholly subsumed by the respective host system functionality.

Turning to the illustrated communication in more detail, the access terminal 120 may transmit and receive messages via a wireless link 130 with the access point 110, the messages including information related to various types of communication (e.g., voice, data, multimedia services, associated control signaling, etc.). The wireless link 130 may operate over a communication medium of interest, shown by way of example in FIG. 1 as medium 132, which may be shared with other communications as well as other RATs. A medium of this type may be composed of one or more frequency, time, and/or space communication resources (e.g., encompassing one or more channels across one or more carriers) associated with communications between one or more transmitter/receiver pairs, such as the access point 110 and the access terminal 120 for the medium 132.

As a particular example, the medium 132 may correspond to at least a portion of an unlicensed frequency band shared with other RATs. In general, the access point 110 and the access terminal 120 may operate via the wireless link 130 according to one or more RATs depending on the network in which they are deployed. These networks may include, for example, different variants of Code Division Multiple Access (CDMA) networks, Time Division Multiple Access (TDMA) networks, Frequency Division Multiple Access (FDMA) networks, Orthogonal FDMA (OFDMA) networks, Single-Carrier FDMA (SC-FDMA) networks, and so on. Although different licensed frequency bands have been reserved for such communications (e.g., by a government entity such as the Federal Communications Commission (FCC) in the United States), certain communication networks, in particular those employing small cell access points, have extended operation into unlicensed frequency bands such as the Unlicensed National Information Infrastructure (U-NII) band used by Wireless Local Area Network (WLAN) technologies, most notably IEEE 802.11x WLAN technologies generally referred to as “Wi-Fi.”

Reducing power consumption is an important criteria for many modern battery-powered electronic devices, such as smaller Internet of Things (IoT) devices that operate on one or more “button” batteries and communicate wirelessly using protocols such as Bluetooth® Low Energy (BLE), BLE Long Range, Bluetooth® Basic Rate (BR), Bluetooth® Enhanced Data Rate (EDR), IEEE 802.15.4 Zigbee, WLAN (802.11a/b/g/n/ah/ac), and the like. In some embodiments, such a device may correspond to the access terminal 120 in FIG. 1.

Employing digital PLLs (DPLLs), also referred to as All-Digital PLLs (ADPLLs), within these devices can significantly lower their power consumption as compared to using analog PLLs (APLLs). A phase lock loop (PLL), or phase-locked loop, is a control system that generates an output signal whose phase is related to the phase of an input signal. For example, in an electronic circuit comprising a variable frequency oscillator and a phase detector that receives a periodic signal as input, the oscillator generates a periodic signal, and the phase detector compares the phase of that signal with the phase of the input periodic signal and adjusts the oscillator to keep the phases matched.

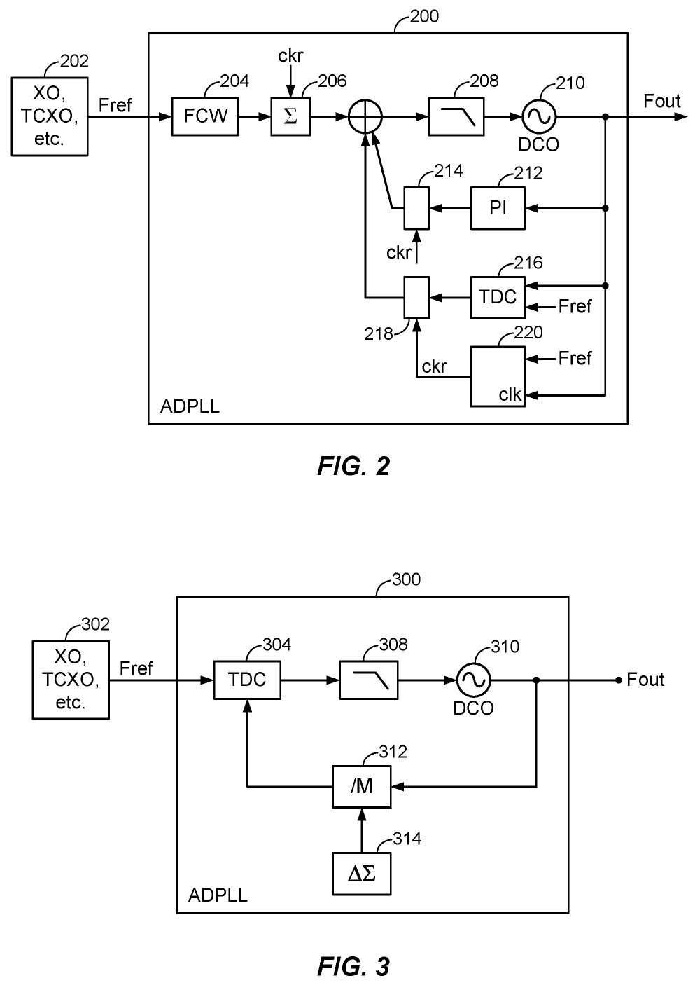

FIG. 2 is a simplified block diagram of an exemplary ADPLL 200. The ADPLL 200 is an example of a phase domain ADPLL, which is a dividerless ADPLL, meaning that every signal into the ADPLL is in the same phase domain. An advantage of such an ADPLL is improved power consumption. The ADPLL 200 may correspond to the ADPLL 142 of the RAT transceiver 140 of the access point 110 and/or the ADPLL 152 of the RAT transceiver 150 of the access terminal 120 of FIG. 1.

As illustrated in FIG. 2, the ADPLL 200 receives a frequency reference (Fref) signal from a crystal oscillator (XO) 202, which may alternatively be a temperature compensated XO (TCXO), or the like. A frequency control word (FCW) 204 (which is the value of the ratio of Fout/Fref and can have low fractionality) receives the Fref and outputs to an accumulator 206, which also receives as input the resampled clock signal (CKR) from clock (CLK) 220. At every CKR, the accumulator 206 adds the FCW 204 to a previously accumulated output. The output of the accumulator 206 is combined with the output signals from flip-flops 214 and 218 (which may be registers), and is passed to a low-pass filter 208. A digital control oscillator (DCO) 210 receives the output signal from the low-pass filter 208 and outputs Fout.

The output signal from the DCO 210 is also passed to a phase incrementer (PI) 212 (a frequency counter), a time-to-digital converter (TDC) 216, and the CLK 220. The TDC 216 and the CLK 220 additionally receive the Fref as input. The PI 212 outputs to the flip-flop 214, and the TDC 216 outputs to the flip-flop 218. Each flip-flop 214 and 218 also receives as input the CKR from the CLK 220, and sends its output to be combined with the output signal from the accumulator 206. The outputs of the PI 212 and the TDC 216 are sampled at every CKR edge. Those values are subtracted from the FCW 204 accumulated value given by the accumulator 206.

FIG. 3 is a simplified block diagram of an exemplary ADPLL 300. The ADPLL 300 is a simpler type of ADPLL than the ADPLL 200. Compared to the ADPLL 200, the ADPLL 300 requires more power, but is less prone to spurs (although it still experiences them). The ADPLL 300 may correspond to the ADPLL 142 of the RAT transceiver 140 of the access point 110 and/or the ADPLL 152 of the RAT transceiver 150 of the access terminal 120 of FIG. 1.

As illustrated in FIG. 3, the ADPLL 300 receives an Fref signal from an XO 302, which may alternatively be a TCXO, or the like. In the ADPLL 300, a TDC 304 receives the Fref and the output from a frequency divider 312 as inputs and outputs to a low-pass filter 308. A DCO 310 receives the signal from the low-pass filter 308 and outputs Fout.

The signal from the DCO 310 is also passed to the frequency divider 312 (which, in the example of FIG. 3, divides the signal by the integer M). The frequency divider 312 additionally receives as input the output of a Sigma-Delta modulator 314, which is used to create a fractional divider out of an integer divider. The frequency divider 312 outputs to the TDC 304. Unfortunately, the benefits of using an ADPLL comes at the cost of higher spurs (i.e., a large spike in the noise level of the output spectrum of the ADPLL) and phase noise that could lead to degradation in the performance of both the receiver and the transmitter devices (e.g., the access point 110 and the access terminal 120, depending on which is receiving or transmitting on the medium 132 at the time). As a result, the receiver and transmitter devices may have difficulty meeting some of the specifications defined in the protocol standards mentioned above (e.g., Bluetooth® Low Energy (BLE), BLE Long Range, Bluetooth® BR, Bluetooth® Enhanced Data Rate (EDR), IEEE 802.15.4 Zigbee, WLAN, etc.) More specifically, higher PLL phase noise and spurs can impact the following specifications:

At the transmitter, higher PLL phase noise and spurs can cause higher Bluetooth® in-band emissions and IEEE 802.15.4/Zigbee Power Spectral Density (PSD), and higher out of band emissions that may fall in the United States Federal Communications Commission (FCC) restricted bands. In addition, the Error Vector Magnitude/Differential Error Vector Magnitude (EVM/DEVM) and Modulation Characteristics may also be impacted if the close-in phase noise and spurs are higher than expected. Note that EVM and DEVM indicate modulation accuracy. EVM indicates how far away the constellation points are from the ideal position for that modulation type, and DEVM is the difference in position of the constellation points from symbol to symbol.

At the receiver, higher phase noise, and specifically spurs, can cause reciprocal mixing of blockers, impacting Bluetooth® Carrier-to-Interference (C/I) at various offsets, as well as IEEE 802.15.4/Zigbee adjacent and alternate channel rejection.

An issue with an ADPLL is that when it is tuned to a channel with a low fractional divide ratio, the number and the level of the fractional spurs can increase. These spurs can fall within the signal bandwidth and degrade the transmitter modulation characteristics and EVM/DEVM. The spurs that are outside of the signal bandwidth can increase the energy that is measured in the adjacent channel, alternate, and other offsets. For example, for Bluetooth® Classic, the signal bandwidth is 1 MHz. Thus, if the transmitter is tuned to 2402 MHz, for example, the signal would occupy 2401.5 MHz to 2402.5 MHz. Spurs that occur in this area may impact signal fidelity, e.g., EVM, DEVM, Modulation Characteristics, etc. Spurs that occur outside of this area may impact emission masks and the band edge, since there is now more energy at these areas from the spurs and phase noise, thereby polluting the spectrum used by other devices.

On the receiver side (e.g., when either the access point 110 or the access terminal 120 is receiving signals over the medium 132), the spurs that are within the signal bandwidth can cause reciprocal mixing of the desired signal, but that are offset by the spur offset. More specifically, the desired signal is down converted by the local oscillator (LO) frequency (which is generated by the PLL) to a lower frequency for signal processing. When there are spurs around this LO, which are also generated by the PLL as an undesired effect, each of these spurs will individually down convert the desired signal again. Thus, if the spurs are within and just outside of the signal bandwidth, the result is multiple down converted desired signals on top of each other but offset by the spur offset. The spur offsets can be anything within or very near the signal bandwidth. For example in the case of 15.4/Zigbee, the signal bandwidth is 2 MHz, so any offset would be within +/−3 MHz.

When outside of the signal bandwidth, the spurs will reciprocally mix with interferes/blockers that are at the same offset. Reciprocal mixing is similar to the spur offset, but the spur frequency and the interfering signal frequency match so that the interference is down converted undesirably to within the signal bandwidth of the receiver. For example, if the receiver bandwidth (which is a little wider than signal bandwidth to pass the signal without attenuation) is, for example, 2.5 MHz, and the receiver is a direct down conversion type and tuned to, for example, 2402 MHz, then if there is an LO spur at a +1 MHz offset generated by the PLL, an interfere/blocker at 2403 MHz will also be down converted by the spur to 0 Hz, on top of the desired signal. This will degrade the sensitivity of the receiver.

Additionally, if the spurs fall at the sampling frequency fundamental and harmonics, aliased versions of the signal will appear at the analog-to-digital converter (ADC) output and degrade receiver sensitivity.

A low fractionality channel occurs when the Fout-to-Fref ratio (Fout/Fref) or the CKV-to-Fref ratio (CKV/Fref), depending on the implementation, results in a ratio that has a very small fractional part. The CKV and Fout are substantially the same. In a particular implementation, rather than use the CKV or Fout directly (e.g., in the Fout/Fref or CKV/Fref ratios), the frequency of the CKV can be divided by two, resulting in a value referred to as CKVd2. In such an implementation, the concept of low fractionality is based on the ratio between CKVd2 and Fref (CKVd2/Fref). Generally, the ratio between the signal that enters the PI (e.g., PI 212 in FIG. 2) and/or the TDC (e.g., TDC 216 in FIG. 2) and Fref is used. The input to the PI and/or the TDC can be the output of the DCO (Fout or CKV) or a divided version of it, as described herein.

As an example implementation, when the DCO (e.g., DCO 210 in FIG. 2) Fout is 2402 MHz, the CKVd2 would be 1201 MHz. With a 40 MHz XO frequency, CKVd2/Fref would be 30.025 (i.e., 1201 divided by 40 is 30.025), with the fractional part being 0.025 (i.e., the fractional part of 30.025). In such a situation, the phase frequency resolution provided by the ADPLL is not fine-grained enough to correct such a small fractional part. Rather, the ADPLL tends to under-correct or over-correct, thereby resulting in fractional spurs.

To address this issue, the present disclosure reduces the number and the level of fractional spurs when an ADPLL is tuned to a low fractionality channel. By increasing the fractional part of the Fout-Fref ratio to, for example, 0.5, while maintaining the same desired ADPLL Fout, the level and the number of the spurs can be reduced. This can be accomplished by employing a non-integer divider, such as a 1.5 divider, before the Fref input to the ADPLL. This effectively changes the Fref frequency in such a way that the resultant FCW avoids scenarios that create large fractional spurs. The reason for increasing the fractional part of the Fout-Fref ratio to approximately 0.5 is because when the fractional part is close to the midpoint in the range 0 to 1, the fractional spur appears at high frequency (e.g., half fref) and is therefore much easier for the loop filter to reduce down. Although the example of 0.5 is given, anywhere around that value would be similarly beneficial.

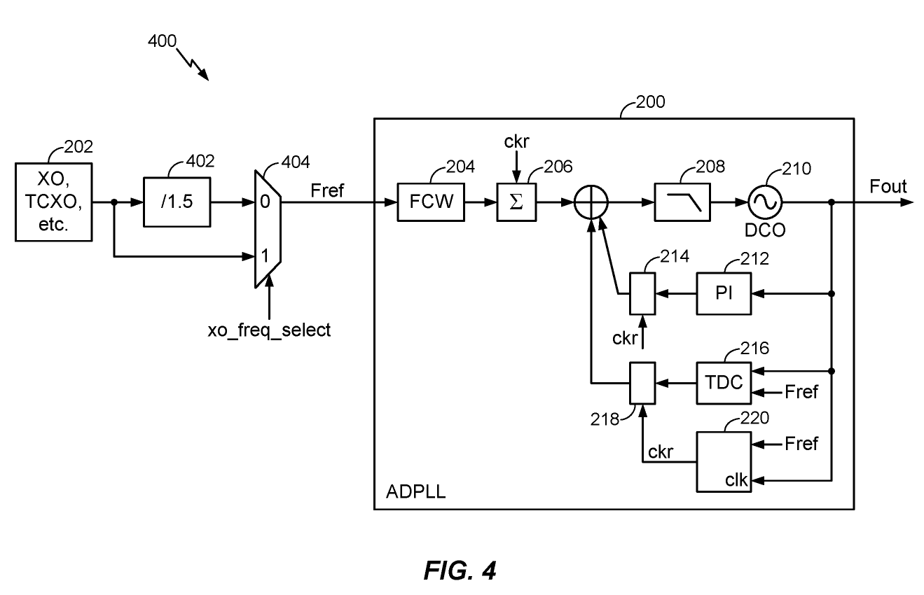

FIG. 4 is a simplified block diagram of an exemplary system 400 in which the ADPLL 200 of FIG. 2 receives input from a non-integer divider 402 according to at least one aspect of the disclosure. As illustrated in FIG. 4, the non-integer divider 402 receives an output signal from the XO 202, divides it by a fractional divide ratio (e.g., 1.5), and outputs the divided signal to a multiplexor (mux) 404. The mux 404 also directly receives the output signal from the XO 202. An xo_freq_select signal selects between input from the non-integer divider 402 and the XO 202. The xo_freq_select signal selects the input from the non-integer divider 402 when the current channel is a low fractionality channel, and selects the input directly from the XO 202 when the channel is not a low fractionality channel.

A channel may be considered a low fractionality channel if the fractional part of the Fout-Fref ratio is below a threshold, e.g., 0.25. To select a channel, the system 400 “dials in an FCW that contains a fractional part (i.e., sets the input of the ADPLL FCW to a number N.F, where N represent the integer part and F the fractional part). Generally, the value of the Fref multiplied by the fractional part is the position of certain spurs in the ADPLL. Depending on the standard or the application, a low fractionality occurs every time the spur location falls in a range where spur specifications are specified by the standard. As such, the low fractionality is very standard-dependent, but it can be assumed that anything that generates spur(s) below a few MHz from the carrier can be identified as a low-fractionality situation.

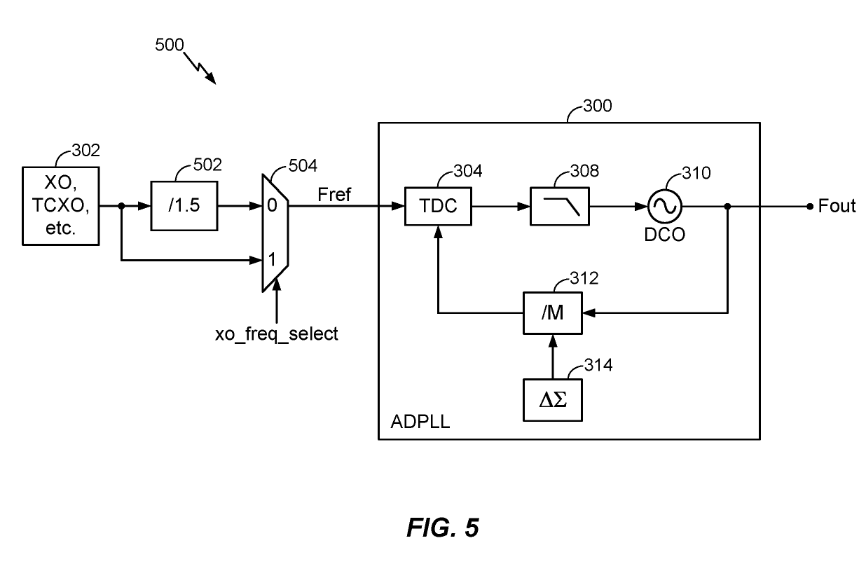

FIG. 5 is a simplified block diagram of an exemplary system 500 in which the ADPLL 300 of FIG. 3 receives input from a non-integer divider 502 according to at least one aspect of the disclosure. As illustrated in FIG. 5, the non-integer divider 502 receives an output signal from the XO 302, divides it by the fractional divide ratio (e.g., 1.5), and outputs the divided signal to a multiplexor (mux) 504. The mux 504 also directly receives the output signal from the XO 302. An xo_freq_select signal selects between input from the non-integer divider 502 and the XO 302. The xo_freq_select signal selects the input from the non-integer divider 502 when the current channel is a low fractionality channel, and selects the input directly from the XO 202 when the channel is not a low fractionality channel.

Note that although the example of a 0.5 Fout-Fref ratio has been presented, as will be appreciated by one of ordinary skill in the art, there are other Fout-Fref ratios that, when the same desired ADPLL Fout is maintained, are also sufficient to reduce the level and the number of spurs. Similarly, although the example of a 1.5 divider has been presented as the non-integer divider 502, as will be appreciated by one of ordinary skill in the art, other non-integer dividers will result in a reduction of the level and the number of the spurs.

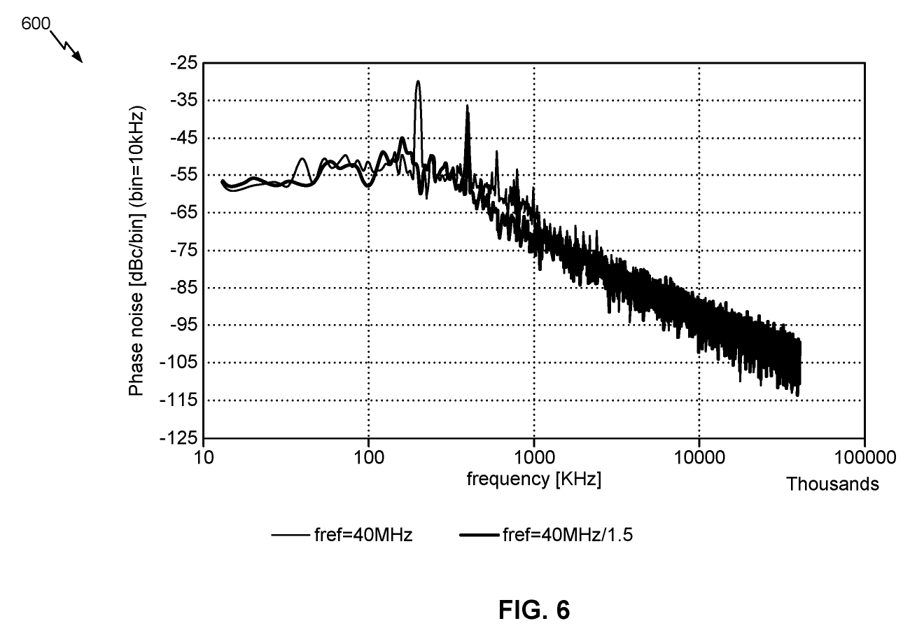

FIG. 6 illustrates a graph 600 of simulation results of a system employing the mechanisms described herein for reducing spurs in an ADPLL using a non-integer divider. As shown in FIG. 6, a major spur occurs at about 200 kHz and is completely eliminated, which is about a 24 dB reduction. The spur at 200 kHz would otherwise be at −28 dB, which would violate both receiver and transmitter requirements. Additionally, the noise hump from 250 kHz-1 MHz is also reduced. Overall, the single-side band integrated phase noise within the 1 MHz range is reduced by approximately 3.5 dB.

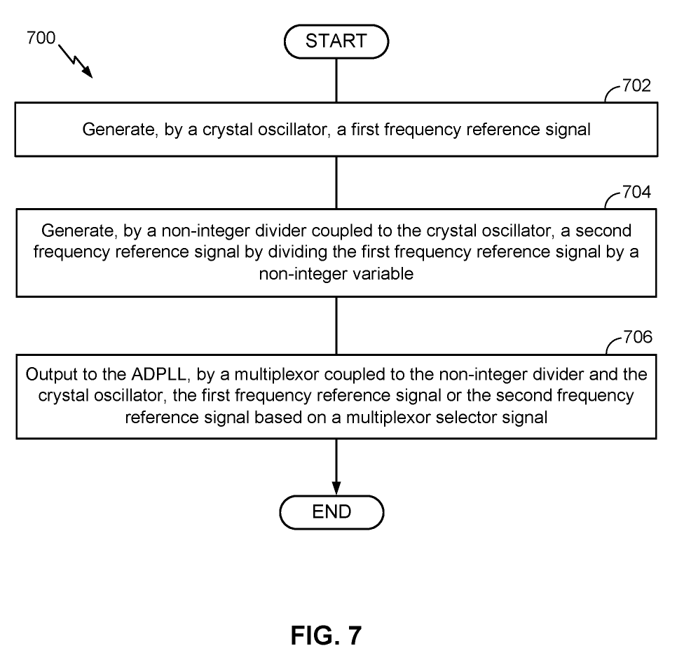

FIG. 7 is a flow diagram illustrating an example method 700 for reducing spurs in an ADPLL, such as the ADPLLs 200/300 in FIGS. 2-5, using a non-integer divider in accordance with the techniques described above. The method 700 may be performed by, for example, components of an access point (e.g., the access point 110 in FIG. 1) or an access terminal (e.g., the access terminal 120 in FIG. 1). More specifically, the method 700 may be performed by, for example, the system 400 in FIG. 4 and/or the system 500 in FIG. 5.

At 702, a crystal oscillator, such as the XOs 202/302, generates a first frequency reference signal, e.g., Fref in FIGS. 2-5.

At 704, a non-integer divider coupled to the crystal oscillator, such as the non-integer dividers 402/502, generates a second frequency reference signal by dividing the first frequency reference signal by a non-integer variable, such as 1.5. In an embodiment, the non-integer variable may be user configurable.

At 706, a multiplexor coupled to the non-integer divider and the crystal oscillator, such as the multiplexors 404/504, outputs to the ADPLL the first frequency reference signal or the second frequency reference signal based on a multiplexor selector signal, such as the xo_freq_select signal. The multiplexor selector signal causes the multiplexor to output the second frequency reference signal based on the ADPLL being tuned to a low fractionality channel. Otherwise, the multiplexor selector signal causes the multiplexor to output the first frequency reference signal based on the ADPLL not being tuned to a low fractionality channel.

As noted above, a low fractionality channel occurs when the ratio of the output of the ADPLL to the first frequency reference signal (e.g., Fout/Fref) results in a ratio that has a low fractional part. A ratio that has a low fractional part may be a ratio that has a fractional part below a fractionality threshold, such as a value of 0.25.

Alternatively, or additionally, a low fractionality channel may be a channel that exhibits large fractional spurs. For example, large fractional spurs may be fractional spurs having a phase noise greater than 10 dB.

Further, the fractional part of the ratio of the output of the ADPLL to the first frequency reference signal (e.g., Fout/Fref) may be approximately 0.5 when the multiplexor selector signal causes the multiplexor to output the second frequency reference signal. The ADPLL may maintain the same output (e.g., Fout) when the multiplexor selector signal causes the multiplexor to output the second frequency reference signal.

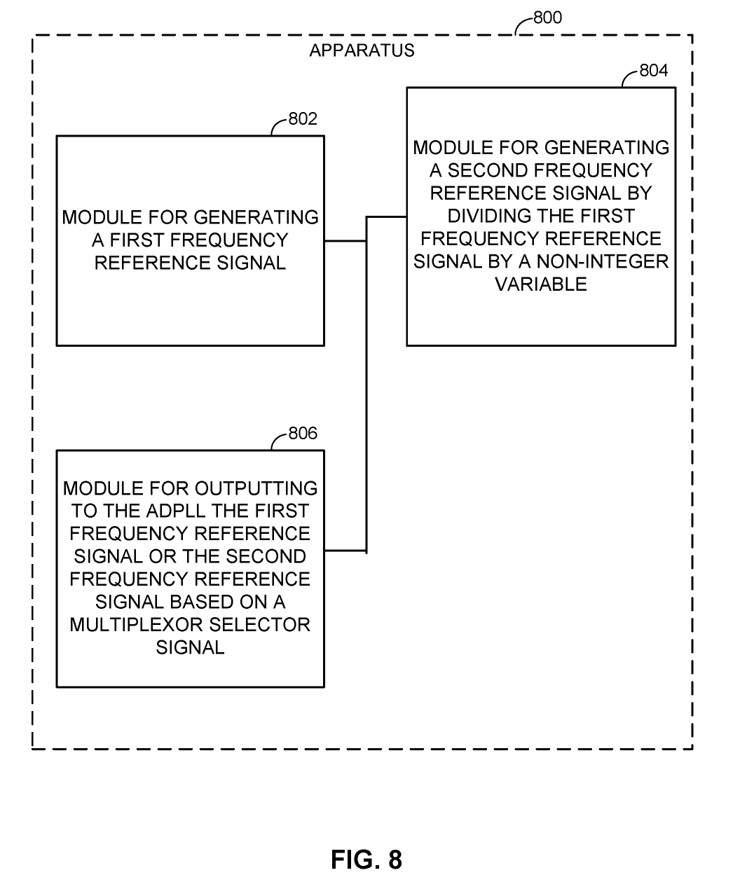

FIG. 8 illustrates an example apparatus 800 (such as the access point 110 or the access terminal 120 in FIG. 1) represented as a series of interrelated functional modules. A module for generating a first frequency reference signal 802 may correspond at least in some aspects to, for example, a crystal oscillator, such as the XO 202 in FIG. 4 or the XO 302 in FIG. 5, as discussed herein. A module for generating a second frequency reference signal 804 may correspond at least in some aspects to, for example, a non-integer divider, such as the non-integer divider 402 in FIG. 4 or the non-integer divider 502 in FIG. 5, as discussed herein. A module for outputting to the ADPLL 806 may correspond at least in some aspects to, for example, a multiplexor, such as the multiplexor 404 in FIG. 4 or the multiplexor 504 in FIG. 5, as discussed herein.

The components and functions represented by FIG. 8, as well as other components and functions described herein, may be implemented using any suitable means. Such means also may be implemented, at least in part, using corresponding structure as taught herein. For example, the components described above in conjunction with the “module for” components of FIG. 8 also may correspond to similarly designated “means for” functionality. Thus, in some aspects one or more of such means may be implemented using one or more of processor components, integrated circuits, or other suitable structure as taught herein.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

In view of the descriptions and explanations above, one skilled in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Accordingly, it will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality.

Moreover, the methods, sequences, and/or algorithms described in connection with the aspects disclosed herein may be embodied directly in hardware, in a software module executed by a processor, or in a combination of the two. A software module may reside in Random-Access Memory (RAM), flash memory, Read-only Memory (ROM), Erasable Programmable Read-only Memory (EPROM), Electrically Erasable Programmable Read-only Memory (EEPROM), registers, hard disk, a removable disk, a CD-ROM, or any other form of storage medium known in the art, transitory or non-transitory. An exemplary storage medium is coupled to the processor such that the processor can read information from, and write information to, the storage medium. In the alternative, the storage medium may be integral to the processor (e.g., cache memory).

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

What is claimed is:

1. An apparatus for reducing fractional spurs in an All-digital Phase Lock Loop (ADPLL), comprising:
a crystal oscillator configured to generate a first frequency reference signal;
a non-integer divider coupled to the crystal oscillator and configured to divide the first frequency reference signal by a non-integer variable to generate a second frequency reference signal; and
a multiplexor coupled to the non-integer divider and the crystal oscillator and configured to output the first frequency reference signal or the second frequency reference signal to the ADPLL,
wherein the multiplexor is configured to output the second frequency reference signal based on the ADPLL being tuned to a low fractionality channel.

2. The apparatus of claim 1, wherein the low fractionality channel occurs when a ratio of an output of the ADPLL to the first frequency reference signal results in a ratio that has a low fractional part.

3. The apparatus of claim 2, wherein the ratio that has the low fractional part comprises a ratio that has a fractional part below a fractionality threshold.

4. The apparatus of claim 3, wherein the fractionality threshold comprises a value of 0.25.

5. The apparatus of claim 2, wherein a fractional part of the ratio of the output of the ADPLL to the first frequency reference signal is approximately 0.5 when the multiplexor outputs the second frequency reference signal.

6. The apparatus of claim 5, wherein the ADPLL is configured to maintain the same output of the ADPLL when the multiplexor outputs the second frequency reference signal.

7. The apparatus of claim 1, wherein the low fractionality channel comprises a channel that exhibits large fractional spurs.

8. The apparatus of claim 1, wherein the non-integer variable comprises a value of 1.5.

9. The apparatus of claim 1, wherein the non-integer variable is user configurable.

10. The apparatus of claim 1, wherein the multiplexor is configured to output the first frequency reference signal based on the ADPLL not being tuned to a low fractionality channel.

11. A method for reducing fractional spurs in an All-digital Phase Lock Loop (ADPLL), comprising:
generating, by a crystal oscillator, a first frequency reference signal;
generating, by a non-integer divider coupled to the crystal oscillator, a second frequency reference signal by dividing the first frequency reference signal by a non-integer variable; and
outputting to the ADPLL, by a multiplexor coupled to the non-integer divider and the crystal oscillator, the first frequency reference signal or the second frequency reference signal,
wherein the multiplexor is configured to output the second frequency reference signal based on the ADPLL being tuned to a low fractionality channel.

12. The method of claim 11, wherein the low fractionality channel occurs when a ratio of an output of the ADPLL to the first frequency reference signal results in a ratio that has a low fractional part.

13. The method of claim 12, wherein the ratio that has the low fractional part comprises a ratio that has a fractional part below a fractionality threshold.

14. The method of claim 13, wherein the fractionality threshold comprises a value of 0.25.

15. The method of claim 12, wherein a fractional part of the ratio of the output of the ADPLL to the first frequency reference signal is approximately 0.5 when the multiplexor outputs the second frequency reference signal.

16. The method of claim 15, further comprising maintaining the same output of the ADPLL when the multiplexor outputs the second frequency reference signal.

17. The method of claim 11, wherein the low fractionality channel comprises a channel that exhibits large fractional spurs.

18. The method of claim 11, wherein the non-integer variable comprises a value of 1.5.

19. The method of claim 11, wherein the multiplexor is configured to output the first frequency reference signal based on the ADPLL not being tuned to a low fractionality channel.

20. An apparatus for reducing fractional spurs in an All-digital Phase Lock Loop (ADPLL), comprising:
a frequency reference signal generating means for generating a first frequency reference signal;
a divider means, coupled to the frequency reference signal generating means, for dividing the first frequency reference signal by a non-integer variable to generate a second frequency reference signal; and
a multiplexing means, coupled to the divider means and the frequency reference signal generating means, for outputting the first frequency reference signal or the second frequency reference signal to the ADPLL,
wherein the multiplexing means outputs the second frequency reference signal based on the ADPLL being tuned to a low fractionality channel.
